(19) United States
(12) Patent Application Publication
(10) Pub. No.: US 2005/0048754 A1
(43) Pub. Date: Mar. 3, 2005

(54) Processing method for increasing packaging density of an integrated circuit

(76) Inventors: Shuang-Feng Yeh, Shanghai (CN); Been Jon Woo, Shanghai (CN)

Correspondence Address: ROSENBERG, KLEIN & LEE, 3458 ELLICOTT CENTER DRIVE-SUITE 101, ELLICOTT CITY, MD, 21043, US

(21) Appl. No.: 10/922,980

(22) Filed: Aug. 23, 2004

(30) Foreign Application Priority Data
Aug. 27, 2003 (CN) 03150608.9

(51) Int. Cl. H01L 21/8234; H01L 21/8244; H01L 21/3205

(52) U.S. Cl. 438/595; 438/585

(57) ABSTRACT

A processing method for increasing the packaging density of an integrated circuit. The processing method of the present invention includes a gate structure on a semiconductor substrate. An oxide film is formed on adjacent lateral sides of a gate structure. A spacer material is conformally deposited on the oxide film and an oxide portion is formed over the spacer material. The oxide portion has a shape to cover an L-shaped portion of the spacer material. The oxide portion is then removed to expose the L-shaped portion of the spacer material. The gate structures having L-shaped spacers benefit from increased packaging density in an integrated circuit, and improve gap filling and prevent contact-to-gate shorts.

### BACKGROUND OF THE INVENTION

1. Field of the Invention

The present invention generally relates to a processing method for improving the packing density of integrated circuits, and more particularly relates to a processing method for improving gap filling and avoiding contact-to-gate shorts.

2. Description of the Prior Art

Spacers are adjacent lateral sides of the gate and are structures under the extension region of the source/drain. Better spacers are silicide dioxide structures. Alternatively, other materials, such as silicide nitride, and silicon oxynitride (SiON), can be used as the spacer materials. Viewing the cross section of the traditional spacer, its shape is usually smooth. The metal-oxide semiconductor field effect transistor utilizes a D-shaped spacer, a triangle oxide spacer, or a trapezoid nitride spacer, wherein these shaped spacers can benefit the shallow source and drain extension and the deep source and drain contact junctions.

The long-term target of integrated circuits is size shrinking and enhancement of the packaging density. The occupied area reduced by the shrunken integrated circuit is very important to the high-speed performance of the integrated circuit. Increasing packaging density can increase the arrangement amount of more semiconductor devices on per area. Additionally, the reduced area of the integrated circuit chip can cause higher yield for integrated circuit manufacturing. However, in order to increase the packaging density, the gap filling of the interlayer dielectric and contact-to-gate short become very difficult challenges. In these different shapes of traditional spacers, the shrunken size and the increased packaging density are not realized.

Therefore, in accordance with the problems mentioned above, the present invention provides a processing method for improving the packing density of integrated circuits and overcomes the disadvantages of conventional technology.

### SUMMARY OF THE INVENTION

According to the purpose of increasing the packaging density mentioned above, the present invention provides a processing method for improving the packaging density of integrated circuits. The present invention utilizes deep sub-micron technology to form L-shaped spacers to effectively improve the packaging density of the integrated circuit.

Another object of the present invention is to provide a processing method utilizing deep sub-micron manufacturing technology which benefits from gap filling and prevents contact-to-gate shorts.

In order to achieve these objects, the present invention provides a processing method for increasing the packaging density of an integrated circuit. The processing method of the present invention includes a gate structure on a semiconductor substrate. An oxide film is formed on adjacent lateral sides of the gate structure. A spacer material is conformally deposited on the oxide film and an oxide portion is formed over the spacer material. The oxide portion has a shape to cover an L-shaped portion of the spacer material. The oxide portion is then removed to expose the L-shaped portion of the spacer material.

Other advantages of the present invention will become apparent from the following description taken in conjunction with the accompanying drawings wherein are set forth, by way of illustration and example, certain embodiments of the present invention.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A, FIG. 1B, and FIG. 1C are drawings illustrating the cross section of a portion of an integrated circuit in accordance with one embodiment of the present invention;

FIG. 2 is a drawing illustrating the cross section after depositing the interlayer dielectric in accordance the FIG. 1C of the present invention; and

FIG. 3A and FIG. 3B are drawings illustrating the cross section of the portion of the integrated circuit in accordance with another embodiment of the present invention.

### DESCRIPTION OF THE PREFERRED EMBODIMENT

While the present invention may be embodied in many different forms, there is shown in the drawings and discussed herein a few specific embodiments with the understanding that the present disclosure is to be considered only as an exemplification of the principles of the invention and is not intend to limit the invention to the embodiments illustrated.

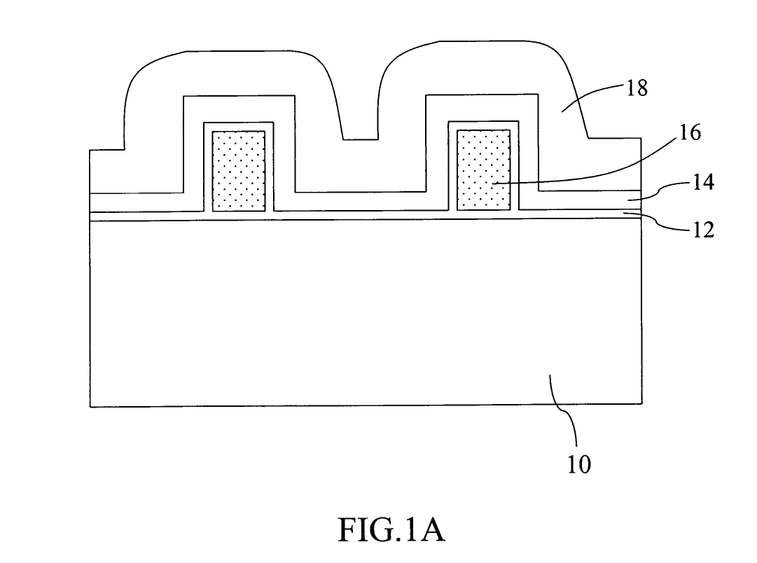

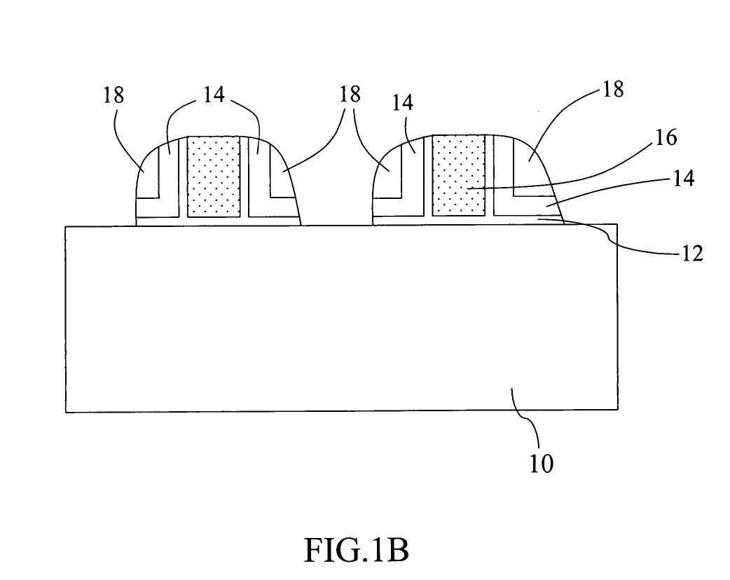

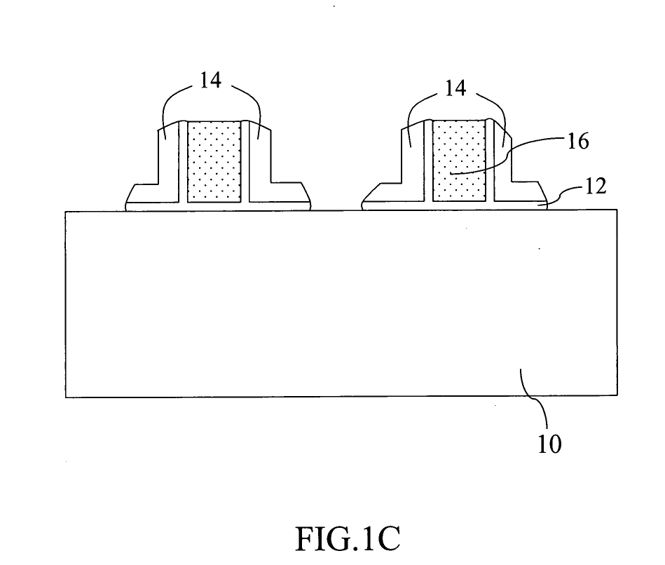

Refer to FIG. 1A, FIG. 1B, and FIG. 1C which are drawings illustrating cross sections of a portion of an integrated circuit in accordance with the present invention. As shown in FIG. 1A, this portion comprises a substrate 10, a gate structure 16, an oxide film 12, a nitride material layer 14, and an oxide layer 18. This portion can be used as the semiconductor chip, such as the integrated circuit portion on the silicon wafer. The substrate 10 can be any appropriate semiconductor material. In one embodiment, the substrate 10 comprises silicon material and also comprises several wells therein. The gate structure 16 can be any appropriate semiconductor material. In this embodiment, the gate structure 16 comprises polysilicon material and the nitride material layer 14 is made of silicon nitride material or other spacer material. The oxide film 12 is formed by an appropriate method and is on adjacent lateral sides of the gate structure 16. The thickness of the oxide film 12 is about 100 angstroms. The nitride material layer 14 is used as a spacer and is conformally formed on the oxide film 12. The thickness of the oxide film 12 is about 300 angstroms. The oxide layer 18 is also formed by an appropriate method and the thickness of the oxide layer 18 is about 1,000 angstroms and larger than the thickness of the nitride material

Referring to the FIG. 1B, a portion of the oxide layer 18, the nitride material layer 14, and the oxide film layer 12 are removed by an etching method. After, the substrate 10 and the top portion of the gate structure 16 are exposed and the residual portion of the oxide layer 18 covers the L-shaped portion of the nitride material layer 14 and the oxide layer 12. The L-shaped portion of the nitride material layer 14 and the oxide layer 12 is on adjacent lateral sides of the gate structure 16.

Following, as shown in FIG. 1C, the residual oxide layer 18 is removed by etching. The L-shaped portion of the nitride material layer 14 is not covered and it can be used as a portion of the L-shaped spacer of the gate structure 16. In accordance with the present invention, the design of the L-shaped spacer 14 of the gate structure 16 can benefit from increased packaging density because it causes easier gap filling and prevents contact-to-gate shorts.

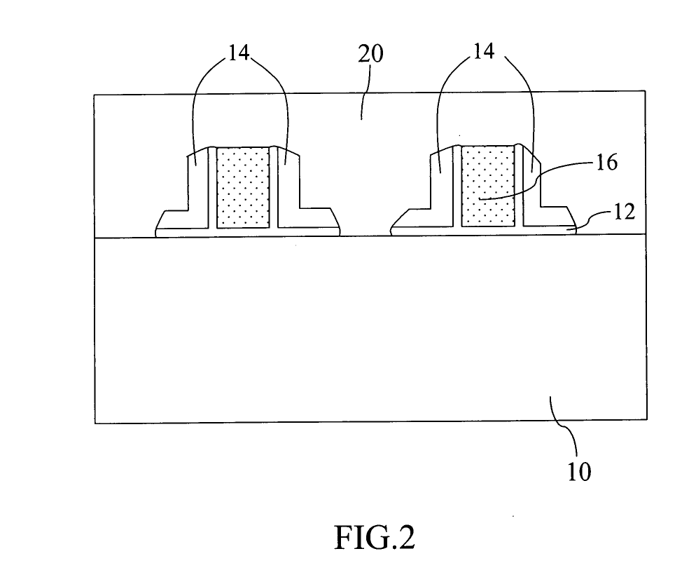

Referring to FIG. 2, performing the deposition of the interlayer dielectric 20, the L-shaped spacer 14 does not obstruct the filling of the interlayer dielectric 20, so the tiny gap between the gate structures 16 can be successfully filled as other portion of the semiconductor. Hence, the L-shaped spacer 14 can benefit from the filling of the interlayer dielectric 20 so as to improve the packaging density of the integrated circuit.

It could be understated that there are many implantation steps in the forgoing steps mentioned above. For example, before the formulation of the oxide film layer 12, there is an ion implantation step by using the gate structure 16 as the implantation mask for the use of the lightly doped region and the drain region. Additionally, before the following steps, there is also a step to perform the ion implantation in the substrate 10 by using the gate structure 16 and the L-shaped spacer 14 as another implantation mask for to be used as the source/drain region.

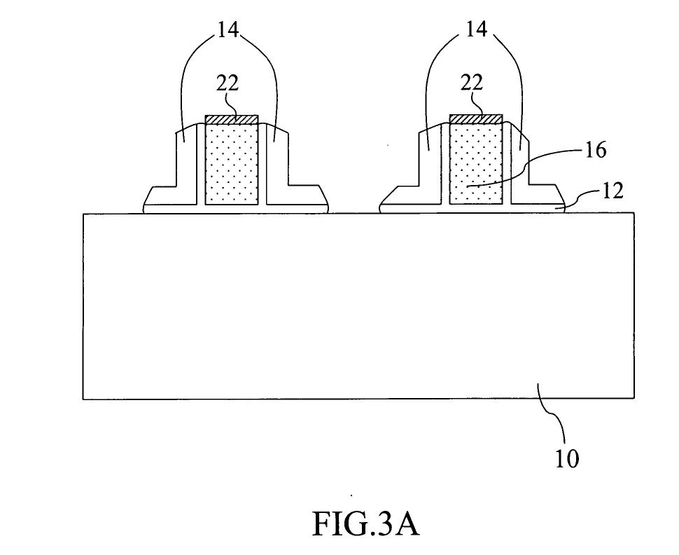

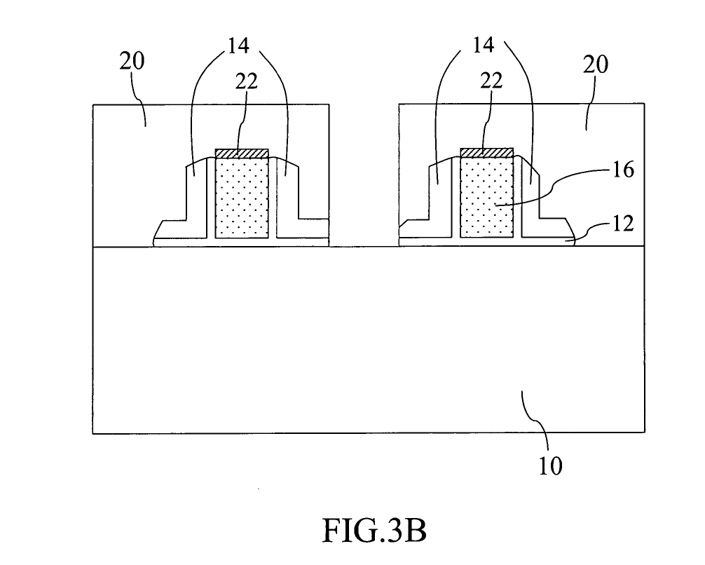

FIG. 3A and FIG. 3B are drawings illustrating the cross section of a portion of the integrated circuit in accordance with another embodiment of the present invention. Referring to FIG. 3A, a self-aligned silicide layer 22 is formed on the top portion of the gate structure 16. Next, the interlayer dielectric 20 is deposited on the substrate 10 and the gate structure 16. Such as shown in FIG. 3B, a portion of the interlayer dielectric 20 is removed so as to form the contact at the gate structure 16.

Hence, compared with the prior art shaped spacer, the L-shaped spacer of the present invention can prevent contact-to-gate shorts.

The forgoing description of the embodiments of the invention has been presented for purposes of illustration and description, and is not intended to be exhaustive or to limit the present invention to he precise from disclosed. The description was selected to best explain the principles of the invention and practical application of these principles to enable others skilled in the art to best utilize the invention in various embodiments and modifications as are suited to the particular use contemplated. It is intended that the scope of the invention not to be limited by the specification, but be defined by the claim set forth below.

1. A processing method for increasing packaging density of an integrated circuit comprising:
forming a gate structure on a semiconductor substrate;
forming an oxide film on adjacent lateral sides of the gate structure;
conformally depositing a spacer material on the oxide film;
forming an oxide portion over the spacer material, wherein the oxide portion has a shape to cover an L-shaped portion of the spacer material; and
removing the oxide portion to expose the L-shaped portion of the spacer material.

2. The processing method according to claim 1, further comprising depositing an interlayer dielectric on the oxide portion and the semiconductor substrate.

3. The processing method according to claim 1, further comprising forming a self-aligned silicide film on the gate structure which is not covered by the oxide film.

4. The processing method according to claim 1, wherein the spacer material comprises nitride material or silicon nitride.

5. A processing method for increasing a packaging density of an integrated circuit comprising:
forming a plurality of gate structures on a semiconductor substrate;
forming a first oxide layer on the semiconductor substrate and the plurality of gate structures;
conformally depositing a nitride layer on the first oxide layer, wherein the nitride layer is thicker than the first oxide layer;
forming a second oxide layer on the nitride layer, wherein the second oxide layer is thicker than the nitride layer; and
removing a portion of the first oxide layer, the nitride layer, and the second oxide layer to expose the semiconductor substrate and a top portion of the plurality of gate structures, wherein a plurality of L-shaped portions of the nitride layer are on adjacent lateral sides of the plurality of gate structures.

6. The processing method according to claim 5, further comprising removing the second oxide layer to expose the plurality L-shaped portions of the nitride layer.

7. The processing method according to claim 6, further comprising forming an interlayer dielectric on the plurality of gate structures and the semiconductor substrate and removing a portion of the interlayer dielectric between the plurality of gate structures so as to form a contact.

8. The processing method according to claim 6, further comprising forming a self-aligned silicide film on a top portion of the plurality of gate structures.

9. The processing method according to claim 6, further comprising using the plurality of L-shaped portions and a portion of the plurality of gate structures as a mask to implant ions in the semiconductor substrate.

10. The processing method according to claim 5, wherein the first oxide layer thickness is about 300 angstroms.

11. The processing method according to claim 5, wherein the second oxide layer thickness is about 1,000 angstroms.

12. The processing method according to claim 5, further comprising using the gate structure as a mask to perform an ion implantation step in the semiconductor substrate.
